(19) United States
(12) Patent Application Publication
(10) Pub. No.: US 2018/0346321 A1
(43) Pub. Date: Dec. 6, 2018

(54) MEMS DEVICE

(71) Applicant: HITACHI, LTD., Tokyo (JP)

(72) Inventors: Chisaki TAKUBO, Tokyo (JP); Atsushi ISOBE, Tokyo (JP); Noriyuki SAKUMA, Tokyo (JP); Yuudai KAMADA, Tokyo (JP); Tomonori SEKIGUCHI, Tokyo (JP)

(21) Appl. No.: 15/912,604

(22) Filed: Mar. 6, 2018

(30) Foreign Application Priority Data
Jun. 6, 2017 (JP) 2017-111277

(51) Int. Cl. B81B 7/02; B81C 1/00; G01P 15/125

(52) U.S. Cl. CPC B81B 7/02; B81C 1/00269; B81B 2201/0235; G01P 15/125; B81C 1/00047

(57) ABSTRACT

An object of the invention is to provide a MEMS device that is easy to set a cavity inner pressure to a desired value by utilizing normally-used MEMS device manufacturing processes and process materials without increase in the number of processes of manufacturing the MEMS device. In order to solve the problem, as a typical MEMS device of the present invention, a MEMS device having a cavity includes an insulating film containing hydrogen in vicinity of the cavity and a hydrogen barrier film covering the insulating film.

### CROSS-REFERENCE TO RELATED APPLICATION

The present application claims priority from Japanese Patent Application No. 2017-111277 filed on Jun. 6, 2017, the content of which is hereby incorporated by reference into this application.

### TECHNICAL FIELD OF THE INVENTION

The present invention relates to a MEMS (Micro Electro Mechanical Systems) device, and, more particularly, to a configuration of a MEMS device in which a pressure inside a cavity needs to be adjusted.

### BACKGROUND OF THE INVENTION

Inmost cases, the MEMS device has a cavity that is air-tightly sealed in order to protect a small movable part, and the small movable part is disposed inside the cavity. It is required to not only prevent infiltration of dust and moisture but also fill an inert gas inside the cavity in order to prevent deterioration of contacts in an RF-MEMS switch or others. Therefore, in an inertial sensor such as an acceleration sensor and an angular velocity sensor, it is required to adjust the pressure inside the cavity to a pressure lower than the atmospheric pressure in order to ensure its performances.

For example, in a resource exploration field, in order to detect weak elastic oscillation that propagates and returns through the ground that causes large damping, a high sensitivity acceleration sensor is required. The MEMS acceleration sensor detects a capacitance change in an oscillator inside the cavity that is a small region, and therefore, is influenced by damping caused by fluid such as air inside the cavity. In order to reduce the influence, in the high sensitivity acceleration sensor, it is required to seal the inside of the cavity to provide a vacuum state. On the other hand, when the pressure is too low, unnecessary oscillation of the oscillator is difficult to stop, and therefore, it takes too long to stabilize the sensor. For this reason, an optimal intra-cavity pressure is set for each sensor.

U.S. Patent Application Laid-open Publication No. 2008/0290494 (Patent Document 1) has been disclosed as a technique for adjusting the pressure inside the cavity to a desired value. In the sensor described in the Patent Document 1, the document describes that the pressure inside the cavity is set to a desired value by forming an air outlet in the cavity after bonding of a wafer configuring layers of the MEMS device and closing the air outlet in a desired vacuum atmosphere.

### SUMMARY OF THE INVENTION

However, in the Patent Document 1, processes of adjusting the pressure inside the cavity while using the air outlet after the bonding of the wafer configuring the layers of the MEMS device, and then, closing the air outlet are added, and therefore, the processes of manufacturing the device increase, and there is a possibility of increase in a manufacturing cost. Moreover, since the air outlet is air-tightly sealed by adhesion between different types of members, a leakage might be caused after a lapse of long period of time, and therefore, this technique has a problem in long-term stability.

In an attempt to adjust the pressure inside the cavity without increasing the processes of manufacturing the MEMS device, the inventors of the present invention have newly found through experiments that hydrogen infiltrates from an insulating film containing hydrogen such as a TEOS film into the cavity.

Accordingly, an object of the present invention is to provide a MEMS device having the pressure inside the cavity that can be easily set to a desired value by utilizing normally-used MEMS device manufacturing processes and process materials without increasing the processes of manufacturing the MEMS device.

As an exemplified typical aspect of means for solving the above-described problems, a MEMS device having a cavity is cited, the MEMS device having features including an insulating film containing hydrogen in the vicinity of the cavity and a hydrogen barrier film covering the insulating film.

According to the present invention, in the MEMS device, the pressure inside the cavity can be adjusted by using the insulating film containing hydrogen in the vicinity of the cavity, so that a MEMS device having high long-term stability and being capable of reducing a manufacturing cost can be provided.

### BRIEF DESCRIPTIONS OF THE DRAWINGS

FIG. 1 is a cross-sectional view of an acceleration sensor according to a first embodiment;

FIG. 2 is a plan view of a MEMS layer of the acceleration sensor according to the first embodiment;

FIG. 3 is a top view of the acceleration sensor according to the first embodiment;

FIG. 4A is a diagram showing measurement results of a pressure inside a cavity in a time course of the acceleration sensor;

FIG. 4B is a diagram showing measurement results of a pressure inside a cavity in a time course of the acceleration sensor;

FIG. 5A is a diagram showing analyzing results of a gas inside the cavity;

FIG. 5B is a diagram showing analyzing results of a gas inside the cavity;

FIG. 6A is an explanatory diagram (for a MEMS layer and a base layer) showing a manufacturing method of the acceleration sensor of the first embodiment;

FIG. 6B is an explanatory diagram (for a MEMS layer and a base layer) showing a manufacturing method of the acceleration sensor of the first embodiment;

FIG. 6C is an explanatory diagram (for a MEMS layer and a base layer) showing a manufacturing method of the acceleration sensor of the first embodiment;

FIG. 7A is an explanatory diagram (for a cap layer formation) showing the manufacturing method of the acceleration sensor of the first embodiment;

FIG. 7B is an explanatory diagram (for a cap layer formation) showing the manufacturing method of the acceleration sensor of the first embodiment;

FIG. 7C is an explanatory diagram (for a cap layer formation) showing the manufacturing method of the acceleration sensor of the first embodiment;

FIG. 7D is an explanatory diagram (for a cap layer formation) showing the manufacturing method of the acceleration sensor of the first embodiment;

FIG. 7E is an explanatory diagram (for a cap layer formation) showing the manufacturing method of the acceleration sensor of the first embodiment;

FIG. 7F is an explanatory diagram (for a cap layer formation) showing the manufacturing method of the acceleration sensor of the first embodiment;

FIG. 8A is an explanatory diagram (for a bonding process) showing the manufacturing method of the acceleration sensor of the first embodiment;

FIG. 8B is an explanatory diagram (for a bonding process) showing the manufacturing method of the acceleration sensor of the first embodiment;

FIG. 9A is an explanatory diagram (for a film-forming process) showing the manufacturing method of the acceleration sensor of the first embodiment;

FIG. 9B is an explanatory diagram (for a film-forming process) showing the manufacturing method of the acceleration sensor of the first embodiment;

FIG. 9C is an explanatory diagram (for a film-forming process) showing the manufacturing method of the acceleration sensor of the first embodiment;

FIG. 10 is a cross-sectional view of an acceleration sensor according to a second embodiment;

FIG. 11 is a plan view of a MEMS layer of the acceleration sensor according to the second embodiment;

FIG. 12 is a top view of the acceleration sensor according to the second embodiment;

FIG. 13 is a cross-sectional view of a composite-type inertial sensor according to a third embodiment;

FIG. 14 is a plan view of a MEMS layer of the composite-type inertial sensor according to the third embodiment; and

FIG. 15 is a top view of the composite-type inertial sensor according to the third embodiment.

### DESCRIPTIONS OF THE PREFERRED EMBODIMENTS

### First Embodiment

Hereinafter, embodiments of the present invention will be described in detail based on the accompanying drawings. Note that the same components are denoted by the same reference symbols in principle throughout all the drawings for describing the embodiments, and the repetitive description thereof will be omitted.

The following description will be made based on an acceleration sensor as one example of the MEMS device. However, the description is not limited to the acceleration sensor as long as the MEMS device is a MEMS device having a cavity such as an angular velocity sensor and an infrared ray sensor because the pressure can be adjusted.

The first embodiment describes a MEMS device in which the pressure inside the cavity can be adjusted to a desired value by forming an insulating film containing hydrogen and a hydrogen barrier film covering the insulating film on an outer surface of a cap layer and by diffusing hydrogen generated from the insulating film into the cavity.

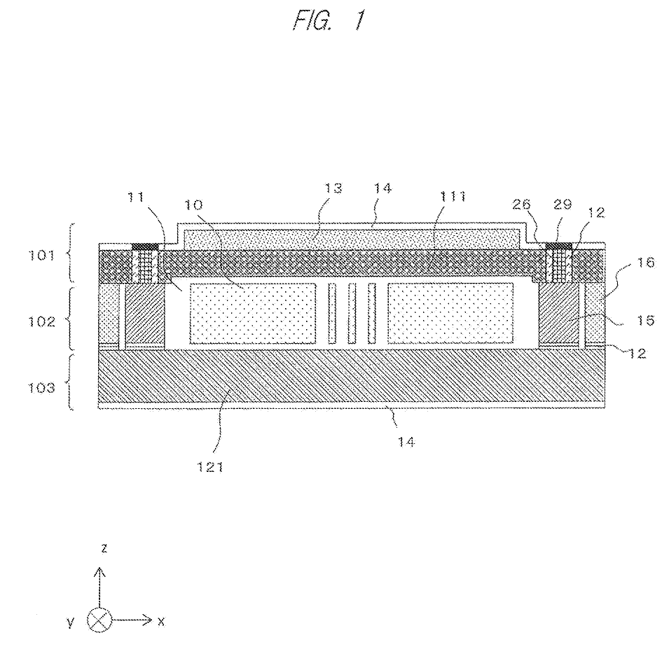

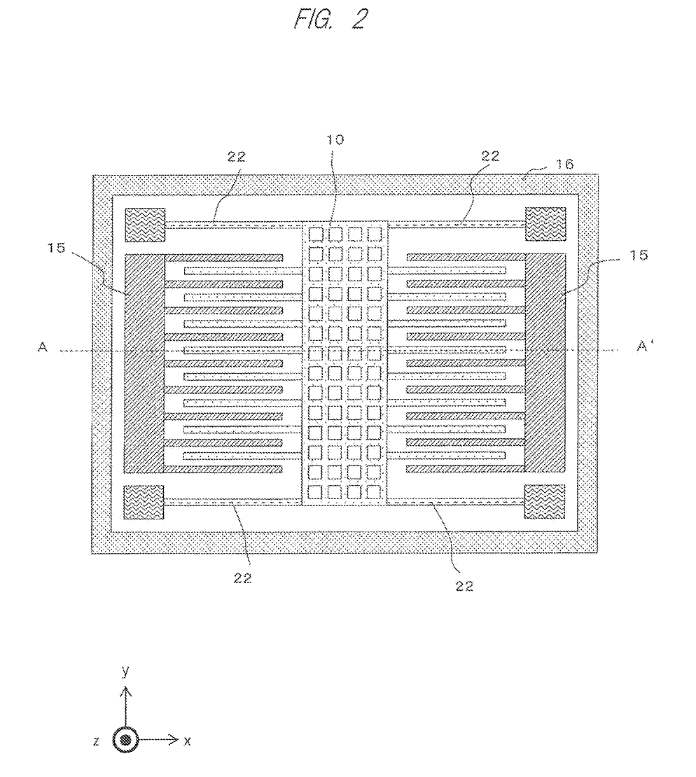

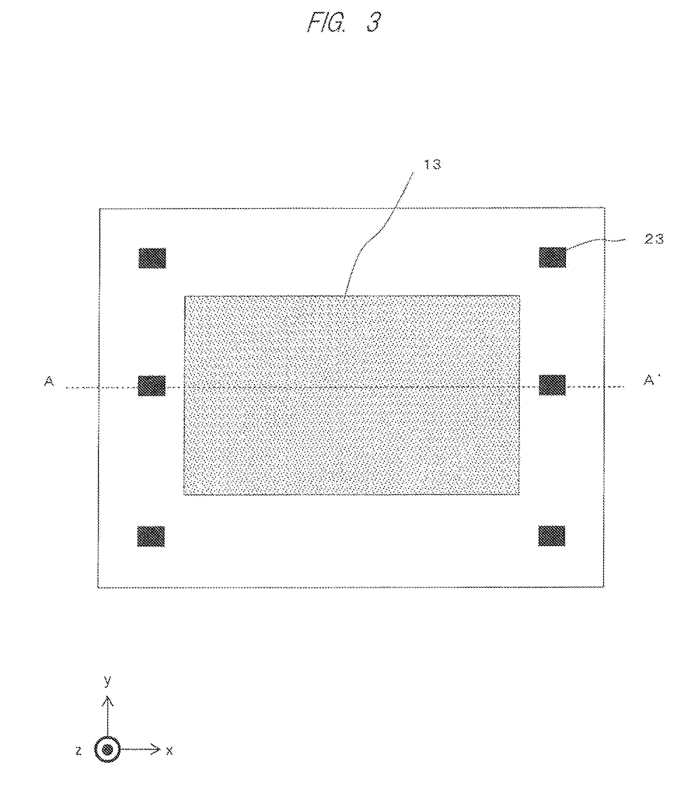

FIG. 1 to FIG. 3 are views each showing a configuration of the acceleration sensor according to the present first embodiment. FIG. 1 is a cross-sectional view of the present sensor, FIG. 2 is a plan view of a MEMS layer of the present sensor, and FIG. 3 is a top view of the present sensor.

FIG. 1 is a cross-sectional view taken along a line A-A′ of FIG. 2. The acceleration sensor is constituted by a cap layer 101, a MEMS layer 102 and a base layer 103, each of which is made from a silicon wafer. For convenience of explanation, an upper layer than the MEMS layer 102 is referred to as the cap layer 101, and a lower layer than the MEMS layer 102 is referred to as the base layer 103.

On the MEMS layer 102, a movable part 10 that can be moved by an acceleration or a tilt is formed, and a cavity 11 is formed in the periphery of the movable part. Moreover, a fixed electrode 15 and a frame 16 are also formed. The layers are bonded to one another directly at silicon parts or through an insulating layer 12, and the cavity 11 is air-tightly sealed by the frame 16 of the MEMS layer 102, the cap layer 101, and the base layer 103. Generally, since the bonding process is performed under a highly vacuumed environment, an inner state of the cavity 11 immediately after the bonding process is a highly vacuumed state.

The insulating film 13 containing hydrogen is formed in the vicinity of the cavity 11 through a silicon substrate 111, and is disposed in an area inside the outer periphery of the MEMS device. A hydrogen barrier film 14 is formed so as to cover the entire upper surface of the cap layer provided with the insulating film 13 containing hydrogen. Moreover, the hydrogen barrier film 14 is also formed on the lower surface of the base layer 103 made of a silicon substrate 121 so as to cover the entire surface thereof. Note that the drawing shows an example is shown in which the insulating film 13 is disposed above the cavity. However, the position of the insulating film may be below the cavity as long as it is located in the vicinity of the cavity. The position of the insulating film can be changed depending on its hydrogen permeability.

In the insulating film 13 containing hydrogen, hydrogen molecules or hydrogen atoms are contained. The hydrogen molecules or hydrogen atoms inside the insulating film 13 above the cap layer 101 can diffuse over the silicon substrate 111 and infiltrate into the cavity 11 because of a large diffusion coefficient in silicon. On the other hand, since the insulating film 13 is covered with the hydrogen barrier film 14 over which hydrogen is difficult to diffuse, the hydrogen molecules or hydrogen atoms are not released to the atmosphere.

In this case, if an inner volume of the cavity 11 has been already known, a pressure inside the cavity 11 can be adjusted to a desired pressure that is lower than a high vacuum pressure generated immediately after the bonding process by adjusting an amount of the hydrogen infiltrating into the cavity 11, that is, a volume of the insulating film 13 containing hydrogen.

FIG. 2 shows a plan view of the MEMS layer 102. The movable part 10 and the fixed electrode 15 are formed, and the movable part 10 is supported by a spring 22 that is displaced in a y-axis direction. The movable part 10 is provided with a movable electrode, and has a configuration that can detect a change amount in a capacitance generated between the fixed electrode 15 and itself when being displaced in the y-axis direction, and therefore, the present acceleration sensor corresponds to a y-axis acceleration sensor. Note that the structure of the MEMS layer 102 of the acceleration sensor described here is simply exemplified, and it is needless to say that the present invention is not limited by the structure shown in the drawing.

FIG. 3 is a top view of the cap layer of the present acceleration sensor. The insulating film 13 containing hydrogen is formed on the inner side of the outer periphery. Moreover, while the hydrogen barrier film 14 is formed on the entire surface so as to cover the insulating film, this layer is omitted in FIG. 3. The hydrogen barrier film 14 at an electrode taking-out portion is removed, and a metal member 23 made of aluminum or others is formed.

A feature of the present first embodiment is to increase the pressure inside the cavity by diffusing the hydrogen generated from the insulating film containing hydrogen formed on the upper surface of the cap layer into the cavity through the silicon of the cap layer.

It is generally known that hydrogen is one of gases each having a large diffusion coefficient in silicon (for example, Helmut Mehre “Diffusion in Solid” Springer (Feb. 15, 2009) P. 414 and others). Generally, a diffusion distance “x” in silicon and an impurity concentration “N(x,t)” at time “t” are obtained from the following diffusion equation. A symbol “N₀” represents a concentration in “x=0” and “t=0”, and a symbol “D” represents a diffusion coefficient.

$$[ Numerical Equation 1 ] \\ [ Numerical Equation 1 ]$$

$$N ( x , t ) = \frac{No}{\sqrt{( π Dt ) exp ( \frac{- {x}^{2}}{4 Dt} )}} \qquad Numerical Equation ( 1 )$$

By using the equation (1) and the diffusion coefficient D described in the above-described document, it is found out that a concentration of the hydrogen diffused in 100 μm of silicon for 60 seconds at 400° C. is 2.3e14 cm⁻³. Meanwhile, when hydrogen of 1e14 cm⁻³ infiltrates into the cavity having a volume of 30 mm³, the pressure inside the cavity becomes 14 Pa at a room temperature based on a gas state equation. From these facts, it is found out that the pressure inside the cavity increases when the amount of the hydrogen outside the cavity is large since the hydrogen is diffused into the cavity through the silicon. On the other hand, a hydrogen volume required for a desired pressure can be obtained by using the volume inside the cavity and the gas state equation. Therefore, from the required hydrogen volume, a suitable volume of the insulating film containing hydrogen can be calculated.

Moreover, when the outside of the insulting film 13 containing hydrogen is covered with the hydrogen barrier film 14, no hydrogen is diffused in a direction of the coverage with the hydrogen barrier film 14, and therefore, the amount of the hydrogen released to the outside becomes as small as possible.

Next, a film quality of each of the insulating film 13 and the hydrogen barrier film 14 will be described. The insulating film 13 is only required to contain the hydrogen molecules or hydrogen atoms in its film. Moreover, the hydrogen barrier film 14 is only required to be a film preventing the diffusion of hydrogen, and usage of, for example, a silicon nitride film that has been conventionally used for a semiconductor device as a hydrogen diffusion prevention film is proposed.

In a process of manufacturing a semiconductor or a MEMS device, silane (SiH4) or TEOS (TetraEthOxySilane: (Si(OC₂H₅)₄)) is sometimes used as a raw material for forming a silicon oxide film. Since each of these materials exists as a gas containing hydrogen atom, the amount of the hydrogen contained in the formed silicon oxide film is also large. It is proposed that, for example, a silicon oxide film (referred to as TEOS film in the present embodiment) formed by a CVD film process using TEOS as the raw material is used as the insulating film 13 containing hydrogen.

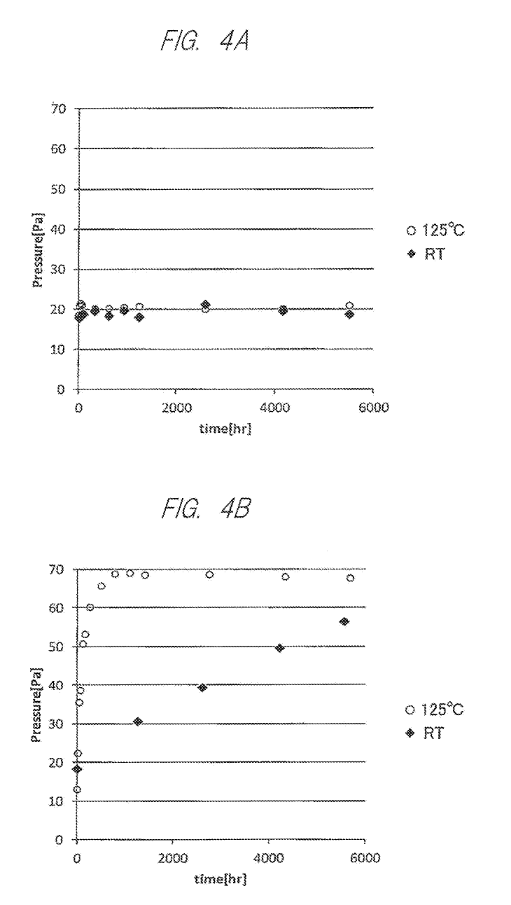

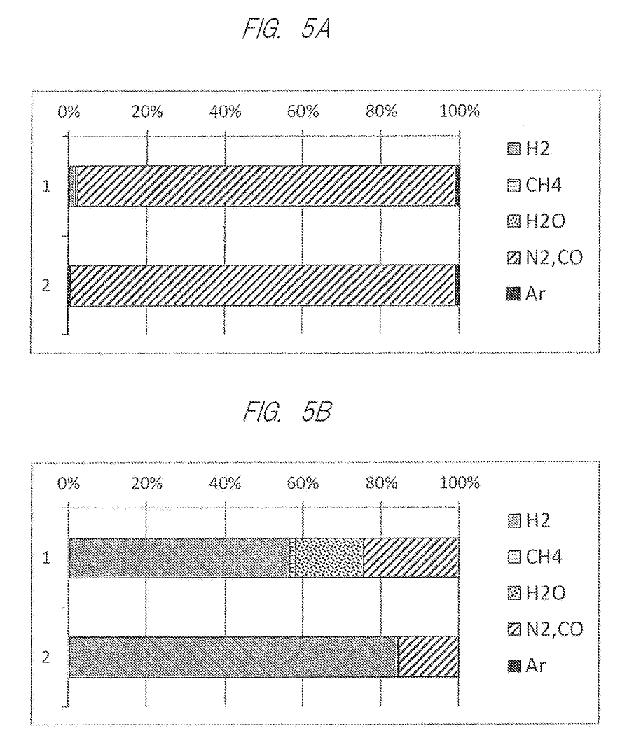

The inventors of the present application have verified a phenomenon of the diffusion of the hydrogen into the cavity by generating the hydrogen from the TEOS film. The results of the verification are described with reference to FIG. 4A to FIG. 5B.

FIG. 4A is a diagram showing measurement of the pressure inside the cavity 11 in a time course of the acceleration sensor without the TEOS film and the silicon nitride film on the upper surface of the cap layer 101. Moreover, FIG. 4B is a diagram showing measurement of the pressure inside the cavity 11 in a time course of the acceleration sensor with the TEOS film and the silicon nitride film covering the TEOS film on the upper surface of the cap layer 101.

The pressure inside the cavity 11 has been checked by an oscillation property of the movable part 10 formed inside the cavity 11. In both of the cases, temporal changes at 125° C. and a room temperature with a pressure at the starting time of 20 Pa have been evaluated.

In FIG. 4A without the insulating film 13 containing hydrogen and the hydrogen barrier film 14, almost no change from the initial pressure has appeared even after 5500 hours. On the other hand, in FIG. 4B with the insulating film 13 containing hydrogen and the hydrogen barrier film 14, phenomena at 125° C. that are increase in the pressure up to 70 Pa after about 800 hours and a stable state in the pressure after the increase have appeared, and even a phenomenon at the room temperature that is gradual increase in the pressure has appeared.

Next, the gas inside the cavity has been analyzed. A volume ratio among the detected gaseous species is shown in FIGS. 5A and 5B. FIG. 5A shows evaluation results of two MEMS devices each without the insulating film 13 (TEOS film) containing hydrogen and the hydrogen barrier film 14 (silicon nitride film) and with the cavity inner pressure of 5 Pa, and FIG. 5B shows evaluation results of two MEMS devices in each of which the insulating film 13 (TEOS film) containing hydrogen has been formed on a cap layer 101 on the device surface and the hydrogen barrier film 14 (silicon nitride film) has been formed on the outside of the insulating film 13 and in each of which the cavity inner pressure has increased up to 33 Pa due to the temporal change at the room temperature. While a nitrogen ratio is large in FIG. 5A, a hydrogen ratio is large in FIG. 5B. As seen in FIG. 5B, in both of the two devices, each volume ratio of the hydrogen has exceeded 50 percent. From these facts, it has been found out that the increase in the pressure inside the cavity is caused by increase in the amount of the hydrogen. By further gas analysis of a thermal desorption spectrometry (TDS) on the TEOS film, a result that is generation of a large amount of the hydrogen in accordance with the increase in the temperature has obtained.

From these results, it has been found out that the pressure inside the cavity can be increased by forming the insulating film containing the large amount of the hydrogen and the hydrogen barrier film so as to cover the insulating film above the cavity.

Generally, the insulating film is formed in order to eliminate surface irregularity due to wirings or others. The Patent Document 1 also discloses a technique of forming an insulating film and a passivation film on one surface in order to protect the MEMS device. The insulating film is formed on the entire surface of the MEMS device for improving the flatness and for a process of manufacturing the insulating film. However, it has been found that because of the film formation on the entire surface, the volume of the insulating film becomes undesirably large, and that the case of the insulating film containing hydrogen changes the pressure inside the cavity due to the hydrogen infiltration so that it is difficult to obtain a predetermined pressure.

When the TEOS film is formed on the entire upper surface of the device as described above, the increased amount of the cavity pressure is considered to become too large. In order to solve this problem, by reducing the amount of the insulating film containing the large amount of the hydrogen by patterning the film, the amount of the generated hydrogen is also reduced, and the increase in the pressure inside the cavity can also be suppressed.

In a semiconductor device, in most cases, a protective film such as a TEOS film, a silicon nitride film or others is formed on the device surface at the last of the manufacturing processes. However, these films are intended to protect the device, and the patterning of the protective film undesirably adds an excessive step flow although being unnecessary from the viewpoint of the processes of forming the semiconductor device, and therefore, these films are normally formed on the entire surface of the device. On the other hand, when the TEOS film is formed on the entire surface in the MEMS device, the amount of the hydrogen generated from the TEOS film becomes large, and therefore, the cavity inner pressure becomes too large.

According to examinations by the inventors of the present application, when a TEOS film (area: 7 mm×7 mm, film thickness: 0.7 μm) having a volume of 3.43e-2 mm³ has been formed, an inner pressure of a cavity having an inner volume of 18.15 mm³ has increased by 50 Pa. For example, in order to control the cavity inner pressure to about 5 Pa, it is required to reduce the volume in the present TEOS film to about one tenth the volume. In order to form the TEOS film on the entire surface of a device and reduce the volume of the TEOS film to one tenth the volume, it is required to form the TEOS film so as to have a thickness of several tens of nm. However, it is difficult to form such a thin film with high reproducibility and without variation in the film thickness. For this reason, it is better not to form the insulating film on the entire surface, but to form a pattern so as to reduce the amount of the TEOS film. The required volume of the insulating film containing hydrogen such as a TEOS film can be adjusted by calculating the increase in the pressure inside the cavity. By disposing the insulating film on the inner side of the outer periphery of the MEMS device, the amount of the insulating film containing hydrogen can be suitably adjusted, so that the pressure inside the cavity can be easily adjusted to a desired value.

Moreover, it is required to form the hydrogen barrier film 14 on the outside of the insulating film 13 containing hydrogen such as the TEOS film. If there is no barrier film, the hydrogen that has infiltrated into the cavity is diffused out of the cavity in course of time, and the cavity inner pressure adversely changes. Meanwhile, on a device side surface where the barrier film is difficult to be formed or on others, the thickness of silicon, that is, a diffusion distance “x” is preferably large based on the equation (1). In order to make the diffusion distance x long, it is proposed to make the length in the x-direction of the frame 16 long as much as possible within a range of a device size. In this manner, the hydrogen inside the cavity can be hardly released within a guarantee period of the device.

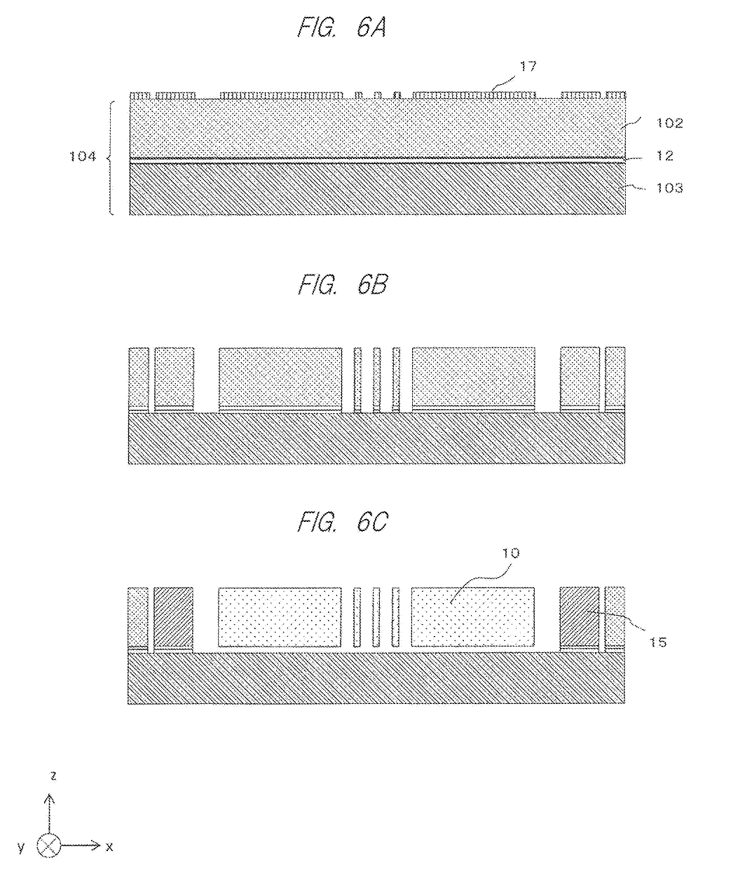

Next, with reference to FIGS. 6A to 9C, one example of a method of manufacturing an acceleration sensor to which the present invention is applied will be described. A resist mask 17 is formed by using an SOI substrate 104 in which a MEMS layer 102 and a base layer 103 each made of silicon are electrically isolated from each other by an insulating layer 12, applying photoresist onto the MEMS layer 102, and transferring a movable part structure of a sensor thereon by a photolithography technique (FIG. 6A). Next, after the movable part structure is formed by a deep reactive ion etching technique on silicon single crystal, the photoresist is removed (FIG. 6B). Next, silicon oxide below the movable part is removed by etching to forma movable part 10, so that a capacitance change caused by a movable state relative to the fixed electrode 15 can be detected (FIG. 6C).

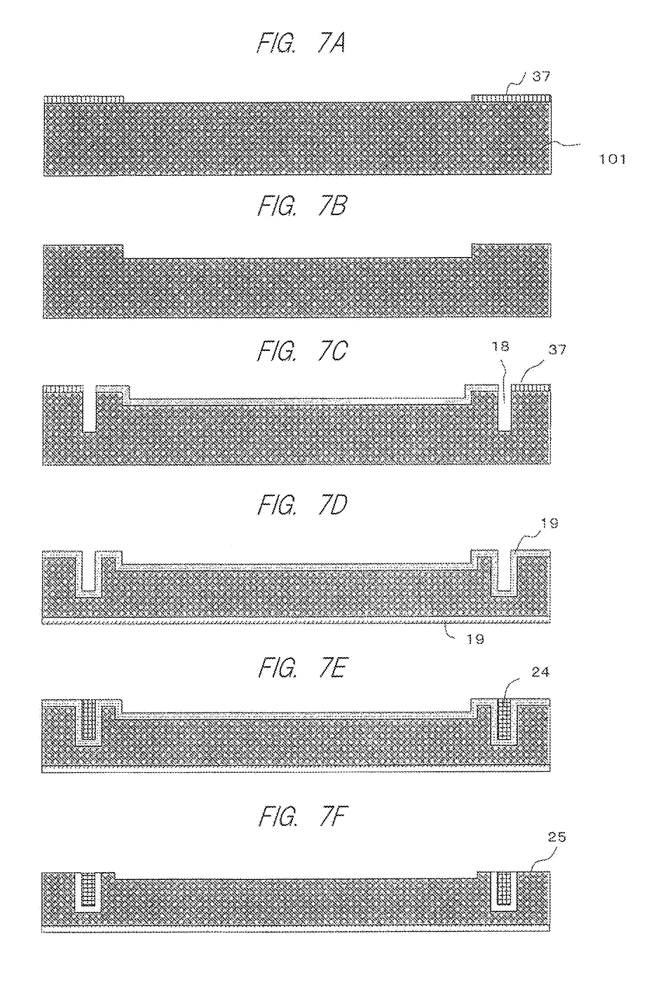

Meanwhile, a cap layer is formed by using another silicon substrate. A resist mask 37 is formed by applying photoresist onto a silicon substrate surface, and transferring a cavity structure thereon by a photolithography technique (FIG. 7A). Then, after the cavity structure is formed by etching, the photoresist is removed (FIG. 7B). Next, in order to form a through electrode for taking out an electrode from the MEMS layer 102, a resist mask 37 is similarly formed, and a through-electrode hole 18 is formed by etching (FIG. 7C). After the resist mask 37 is removed, an insulating layer 19 made of silicon oxide is formed on the silicon wafer surface including the hole side surface by thermal oxidation (FIG. 7D). Next, a conductive material such as polysilicon 24 is embedded into the hole 18 but the material deposited on a portion except for the hole 18 is removed (FIG. 7E), and the upper surface of the wafer, that is, a surface 25 to be bonded is flattened (FIG. 7F).

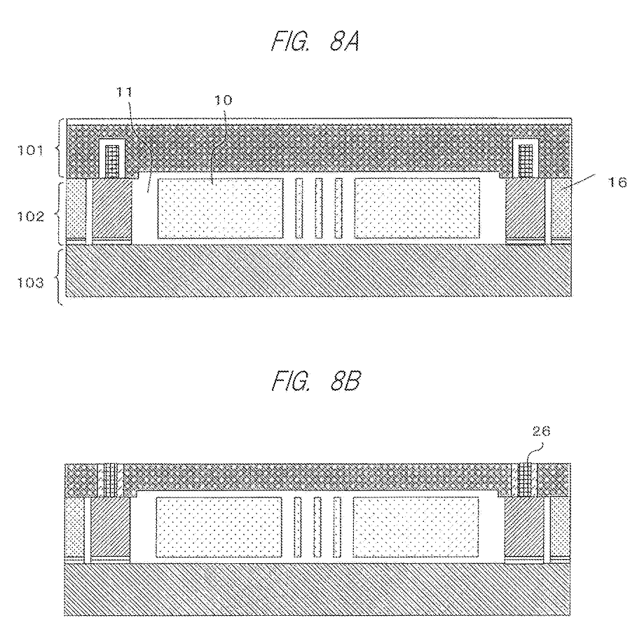

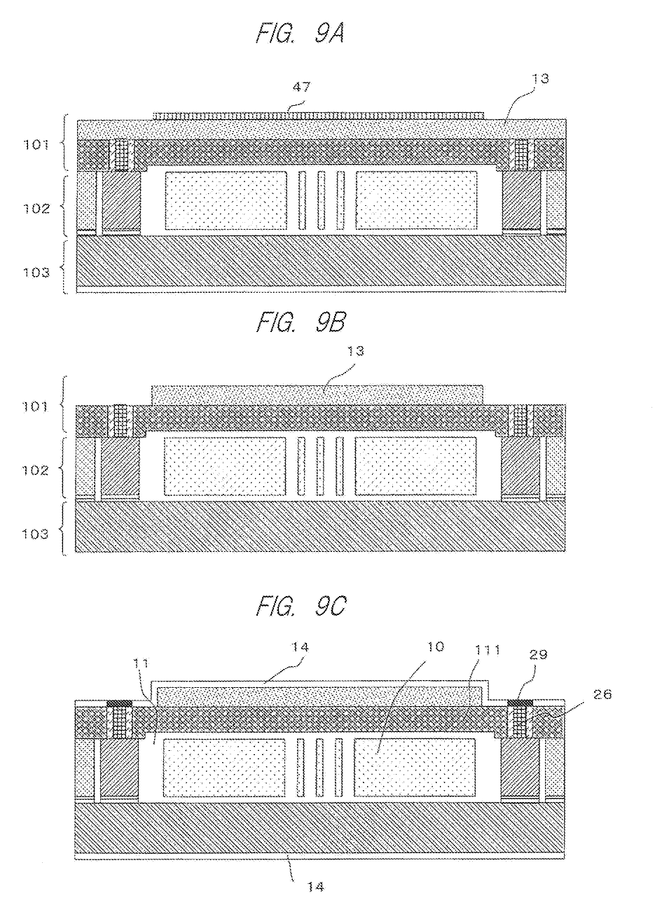

Moreover, by bonding and air-tightly sealing the respective wafers manufactured in FIGS. 6A to 7F, the cavity 11 is formed on the periphery of the movable part 10 (FIG. 8A). The cavity 11 is sealed by the cap layer 101, the base layer 103 and a frame 16 of the MEMS layer 102. Then, the upper surface of the cap layer 101 is polished to expose the through electrode 26 (FIG. 8B). Lastly, in order to adjust the pressure inside the cavity 11, a TEOS film pattern serving as the insulating film 13 containing hydrogen and a silicon nitride film serving as the hydrogen barrier film 14 are formed. On the upper surface of the cap layer 101, the insulating film 13 containing hydrogen such as a TEOS film is formed, and a resist mask 47 having a size supporting the hydrogen generation amount is formed (FIG. 9A). The insulating film 13 containing hydrogen is patterned by etching (FIG. 9B), and the hydrogen barrier film 14 such as a silicon nitride film is formed on the entire surface of the patterned insulating film so as to cover the insulating film 13. Next, by removing the hydrogen barrier film 14 at an electrode taking-out opening, an aluminum pad 29 for taking out an electrode is formed. Moreover, in order to prevent the release of the hydrogen also to the outside of the base layer 103, the hydrogen barrier film 14 such as a silicon nitride film is formed (FIG. 9C). Lastly, hydrogen inside the TEOS film is made to infiltrate into the cavity by performing a heating process, so that the pressure inside the cavity is set to a desired pressure. In order to shorten the distance in which hydrogen is diffused inside silicon, a thickness of the silicon substrate 111 is preferably small. For example, the thickness of the silicon substrate 111 above the cavity is set to about 100 μm. By thinning the silicon substrate 111, time taken to set the pressure inside the cavity to a desired value can be shortened, and a heating temperature used for allowing the hydrogen inside the insulating film 13 to infiltrate into the cavity 11 can be made low.

In the present first embodiment, note that an upper silicon part of the SOI substrate is formed as the MEMS layer 102, and a lower silicon part of the same is formed as the base layer 103. However, the SOI substrate may not be used, and a MEMS layer substrate may be bonded to a base layer substrate.

Moreover, the amount of the hydrogen inside the film is different depending on a material of and a film-forming condition of the silicon oxide film. In this case, a pattern size may be adjusted depending on a hydrogen concentration inside the silicon oxide film to be formed.

As described above, in the MEMS device according to the present embodiment, a MEMS device having the cavity 11 has a feature including the insulating film 13 containing hydrogen in the vicinity of the cavity 11 and the hydrogen barrier film 14 covering the insulating film 13.

In the above-described configuration, the pressure inside the cavity 11 can be set to a desired value by optimizing the volume of the insulating film 13 formed in the last process. Since the pressure inside the cavity 11 can be adjusted by adjusting the insulating film 13 formed in the vicinity of the cavity, a MEMS device having high long-term stability and being capable of reducing a manufacturing cost can be provided.

Moreover, the MEMS device according to the present embodiment has a feature including a silicon substrate 121 below the cavity 11 and a second hydrogen barrier film 14 covering a lower surface of the silicon substrate 121.

In the above-described configuration, the diffusion of the hydrogen filled inside the cavity 11 from the silicon substrate side 121 below the cavity 11 to the atmosphere can be prevented, and therefore, the pressure inside the cavity 11 can be easily maintained at a desired pressure for a long period of time.

### Second Embodiment

A second embodiment will describe a MEMS device in which the hydrogen can quickly infiltrate into the cavity through a separation layer by forming the separation layer on the cap layer above the cavity and forming the insulating film containing hydrogen on the separation layer.

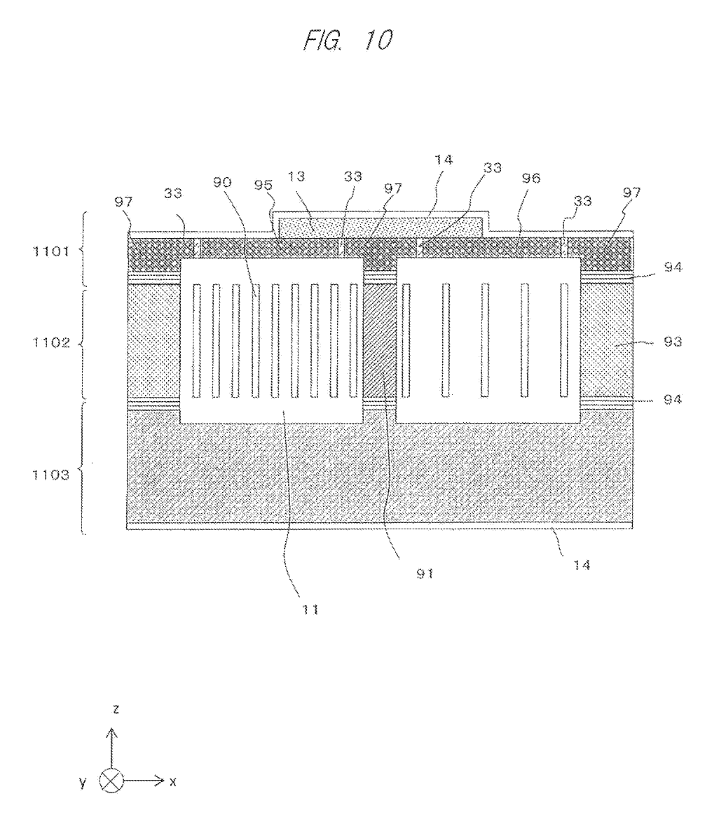

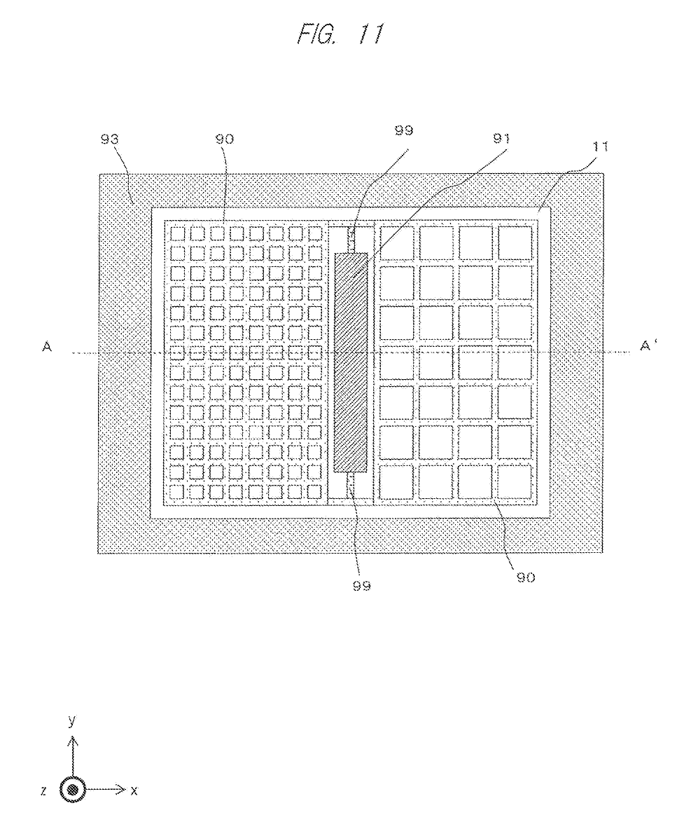

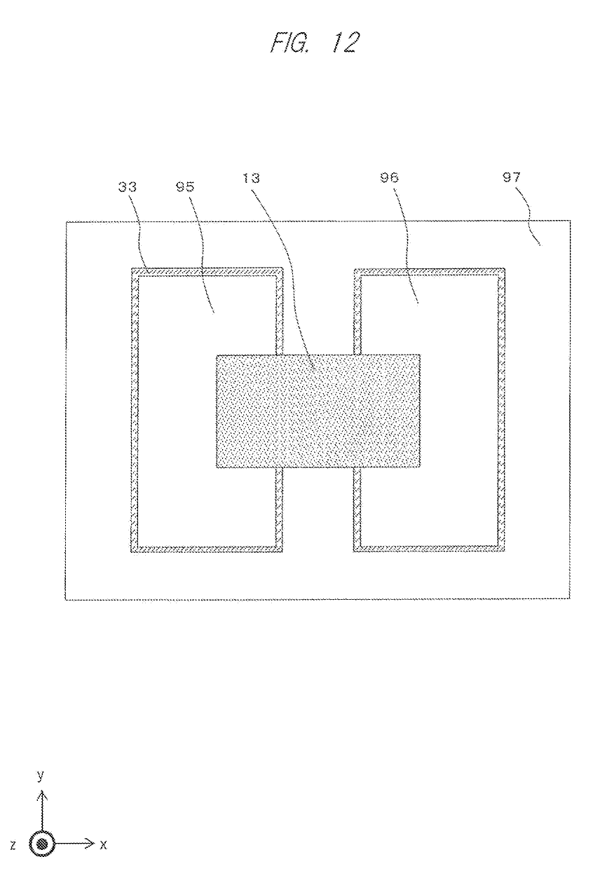

FIG. 10 to FIG. 12 are diagrams each showing a structure of an acceleration sensor that is a MEMS device in the present second embodiment. FIG. 10 is a cross-sectional view of the present sensor, FIG. 11 is a plan view of the MEMS layer, and FIG. 12 is a top view of the present sensor.

FIG. 10 shows a cross-sectional surface taken along a line A-A′ of FIG. 11. The device is configured of a MEMS layer 1102 where a movable part 90 that is movable by an acceleration or a tilt, a fixed part 91 that supports the movable part 90 and a frame 93 are formed, and a cap layer 1101 and a base layer 1103 that air-tightly seal the movable part 90 therebetween. The respective layers are directly bonded to one another through the insulating layer 94. For convenience of explanation, an upper layer of the MEMS layer 1102 is referred to as a cap layer 1101, and a lower layer of the same is referred to as a base layer 1103. The movable part 90 formed on the MEMS layer 1102 is configured to move in a “z” direction as a seesaw on the fixed part 91 serving as a pivot axis. In FIG. 10, a left side of the fixed part 91 is dense. Therefore, when the gravity is applied in the “−z” direction, the left side is tilted in the −z direction. Moreover, right above the movable part 90 in the cap layer 1101, an electrode 95 and an electrode 96 that are paired with the movable parts 90 to detect a capacitance are formed. For this reason, the acceleration sensor of the present second embodiment corresponds to a z-axis acceleration sensor in which the movable part 90 is movable in the z-axis direction by an acceleration or a tilt so that a change amount in the capacitance caused between the movable part and the electrodes 95 and 96 formed in the cap layer 1101 can be detected.

An electrode of the cap layer 1101 is formed by separating the part 95 and the part 96 serving as the electrodes from another external area 97 of the cap layer 1101 by a separation layer 33. Since the electrode penetrates the cap layer, it is referred to also as through electrode.

The separation layer 33 may have any structure as long as its crystallinity is poorer than that of single crystal silicon. For example, the structure is a structure only with an insulating film made of silicon oxide or others or a structure containing an embedding material such as polysilicon that is embedded between the insulating film and the separation layer. Since the insulating film and the embedding material are poorer in crystallinity than single crystal silicon of the cap layer 1101, the hydrogen is easily infiltrated into the cavity 11 through the separation layer 33. By forming the insulating film 13 containing hydrogen on the separation layer 33 for utilizing this property, a speed of the hydrogen infiltration into the cavity 11 can be made large, so that the time for the pressure adjustment can be shortened, and the heating temperature can be lowered. The hydrogen barrier film is formed on the upper surface of the cap layer 1101 so as to cover the insulating film 13, and is also formed on the lower surface of the base layer 1103.

FIG. 11 is a plan view of the MEMS layer 1102. The movable part 90 and the fixed part 91 supporting the movable part 90 are formed, and the movable part 90 is connected to the fixed part 91 through a spring 99. Moreover, since these members are surrounded by the frame 93, the cavity 11 is air-tightly sealed by the bonding between the cap layer 1101 and the base layer 1103.

FIG. 12 is a top view of the cap layer 1101 of the present sensor. The insulating film 13 containing hydrogen is formed above the separation layer 33 for separating the electrode 95 and the electrode 96 from the external area 97. Although the hydrogen barrier film 14 is formed on the entire device surface so as to cover the insulating film 13 and the cap layer 1101, this film is omitted in the drawing. The aluminum pad serving as the taking-out electrode is also omitted.

As described above, the MEMS device according to the present example has a feature including, in addition to the MEMS device described in the first embodiment, the separation layer 33 made of a material having poorer crystallinity than that of single crystal silicon that is formed between the insulating film 13 containing hydrogen and the cavity 11, the separation layer 33 being formed so as to penetrate the cap layer 1101. Moreover, the MEMS device has a feature making the separation layer 33 from a material that is only an insulating film made of silicon oxide or from an insulating film made of the silicon oxide and an embedding material made of polysilicon.

According to the above-described configuration, the pressure inside the cavity 11 can be quickly adjusted by allowing the hydrogen to infiltrate from not only silicon but also the separation layer 33. Therefore, even when the cap layer 1101 is thick, the pressure can be adjusted in a short time. Moreover, the speed of the hydrogen infiltration can be changed by changing the crystallinity of the embedding material of the separation layer 33.

### Third Embodiment

A third embodiment will describe that, when a plurality of different MEMS devices are formed on the same substrate, the MEMS devices that can be adjusted to have different cavity pressures from one another are provided by forming different-sized insulating films containing hydrogen on the upper surfaces of the cap layers above the respective cavities. The present embodiment has a feature that can adjust the pressure inside the cavity of each sensor by forming an optimal pattern for each of various sensors manufactured on the same substrate since the hydrogen generation amounts can be individually adjusted by the pattern size of each insulating film containing hydrogen.

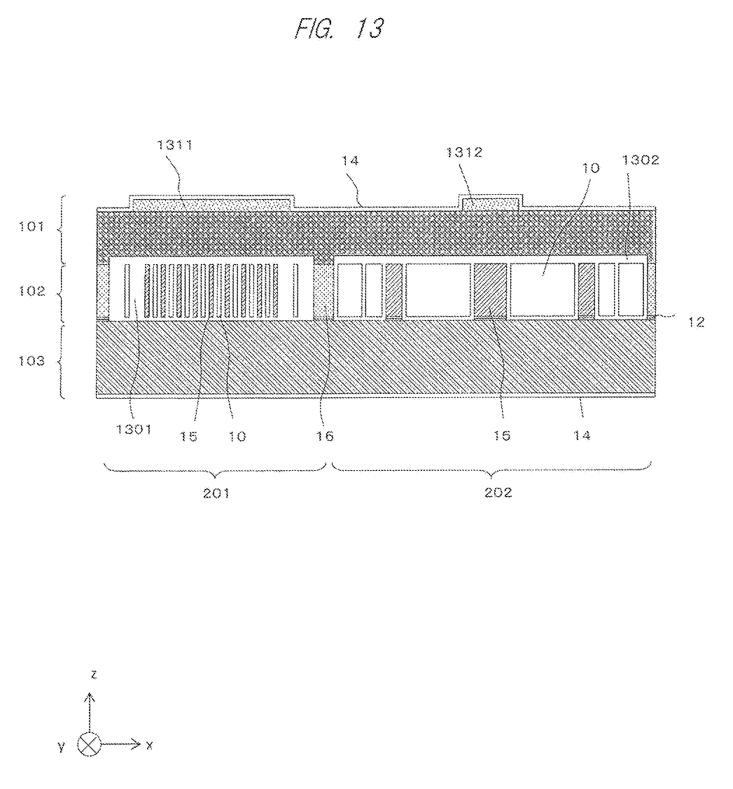

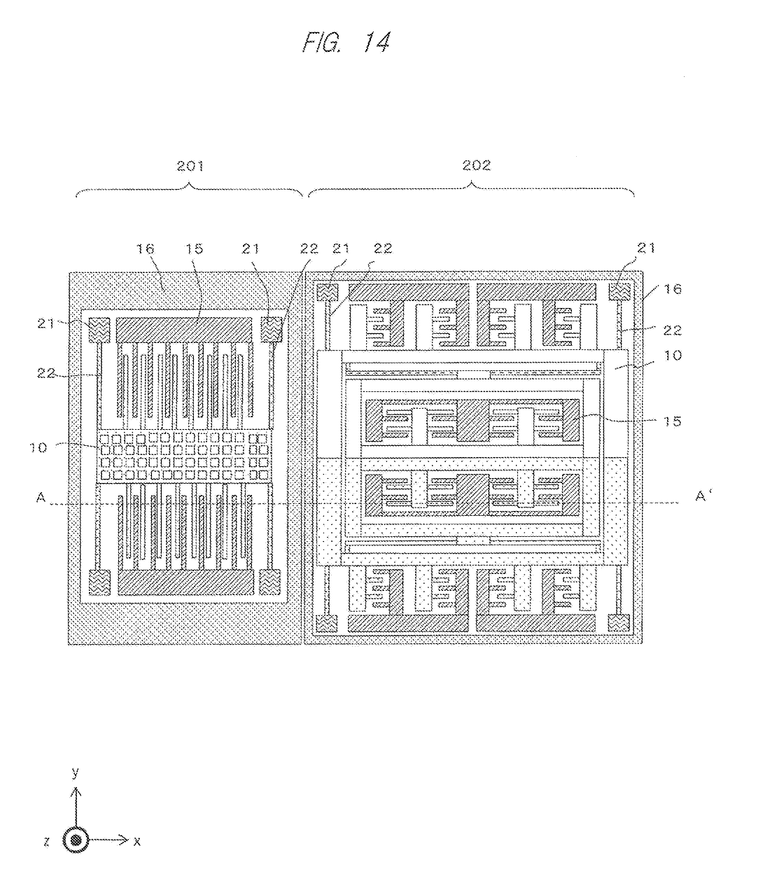

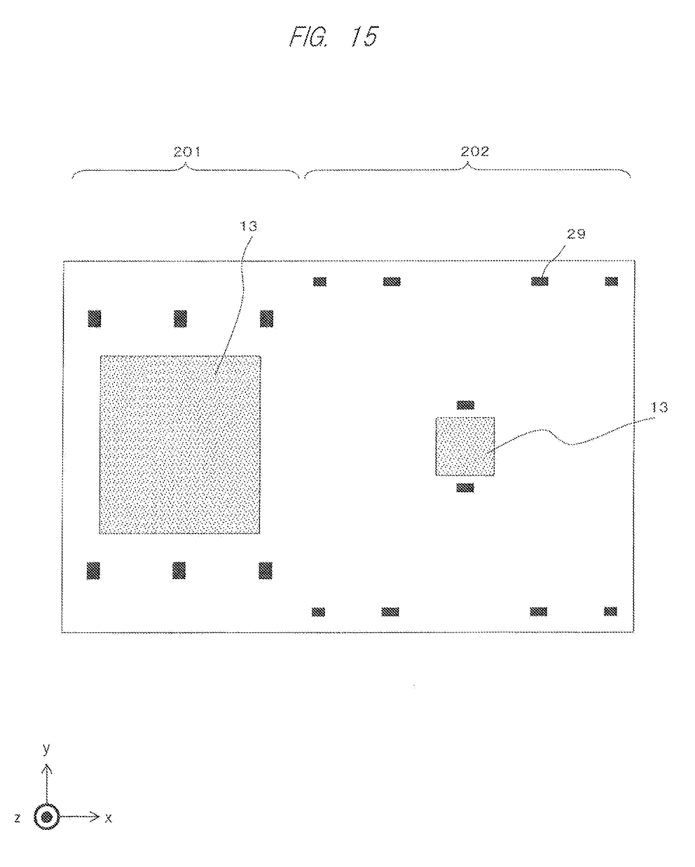

FIG. 13 to FIG. 15 are diagrams each showing a structure of a composite-type inertial sensor configured of an acceleration sensor and an angular velocity sensor of the MEMS device according to the present third embodiment. FIG. 13 is a cross-sectional view of the present sensor, FIG. 14 is a plan view of the MEMS layer of the present sensor, and FIG. 15 is a top view of the present sensor. In each of the drawings, an acceleration sensor 201 is shown on the left side, and an angular velocity sensor 202 is shown on the right side. The cavities of the angular velocity sensor and the acceleration sensor are separated from each other by a frame 16, and are air-tightly sealed in different pressures from each other.

FIG. 13 is a cross-sectional surface taken along a line A-A′ of FIG. 14. The device is configured of the MEMS layer 102 where each movable part 10 of the acceleration sensor 201 and the angular velocity sensor 202, the fixed electrode 15 and the frame 16 are formed, and the cap layer 101 and the base layer 103 that air-tightly seal cavities 1301 and 1302 therebetween. In the present embodiment, an upper layer in the drawing is prepared as the cap layer, and a lower layer therein is prepared as a base layer. However, these layers may be opposite to each other. In the cap layer above of the cavity of each sensor, insulating films 1311 and 1312 containing hydrogen are formed, and a hydrogen barrier film 14 is formed on the entire upper surface of the composite-type inertial sensor so as to cover these insulating films. In the present third embodiment, in order to make an inner pressure of the cavity 1301 of the acceleration sensor 201 lower than an inner pressure of the cavity 1302 of the angular velocity sensor 202, the pattern size of the insulating film is made larger. The hydrogen barrier film 14 is also formed on the lower surface of the composite-type inertial sensor.

FIG. 14 is a plan view of the MEMS layer 102. The acceleration sensor 201 is a y-axis acceleration sensor that detects a change amount in a capacitance generated when the movable part is displaced in the “y” axis direction by an acceleration or a tilt, and the angular velocity sensor 202 is an angular velocity sensor that detects an angular velocity relative to the “z” axis. The structure shown in FIG. 14 is one example, and it is needless to say that structures of both of the acceleration sensor and the angular velocity sensor are not limited to this structure.

FIG. 15 is a top view of the cap layer 101 according to the present third embodiment. The insulating film 13 containing hydrogen is formed on a part of the upper surface. Moreover, the hydrogen barrier film 14 is formed on the entire surface of the cap layer 101 so as to cover the insulating film. However, the insulating film is omitted in the drawing. The hydrogen barrier film 14 to be the electrode part is removed, and an aluminum pad 29 is formed.

Generally, suitable cavity inner pressures of the acceleration sensor 201 and the angular velocity sensor 202 are different from each other. Since the cavities formed on the same substrate are simultaneously bonded, the pressures inside the plurality of cavities are made equal to one another. In order to adjust these pressured to different pressures from one another, in the present third embodiment, the amount of the insulating film containing hydrogen that is formed above the cavity, that is, the pattern size is changed.

In FIG. 13 and FIG. 15, the insulating film 1311 containing hydrogen that has a large pattern is formed for the acceleration sensor 201 whose suitable cavity inner pressure is low, and the insulating film 1312 containing hydrogen that has a small pattern is formed for the angular velocity sensor 202 whose suitable cavity inner pressure is high. As a result, when the amount of the insulating film containing hydrogen becomes different, the amount of the hydrogen infiltrating into the cavity also becomes different, and therefore, the values of the cavity inner pressures of the acceleration sensor 201 and the angular velocity sensor 202 can be adjusted to different values from each other. Normally, when the two cavity inner pressures are adjusted to have the different values from each other, it is required to perform the air-tightly sealing process twice under different pressure atmosphere from each other. However, in the composite-type inertial sensor according to the present example, the two cavity inner pressures can be adjusted to have the different values from each other by performing the air-tightly sealing process once, the manufacturing costs can be reduced.

Moreover, the present third embodiment describes the example of the composite-type inertial sensor configured of total two sensors that are the acceleration sensor and the angular velocity sensor. However, when the through electrode described in the second embodiment is utilized, acceleration sensors for x, y and z axes and angular velocity sensors for x, y and z axes can be formed on the same substrate as one another.

As described above, the composite-type MEMS device according to the present example having a plurality of cavities has a feature including the first insulating film 1311 containing hydrogen above the first cavity 1301, the second insulating 1312 containing hydrogen above the second cavity 1302, and the hydrogen barrier film 14 that covers the first insulating film 1311 and the second insulating film 1312, and a feature in which the first insulating film 1311 and the second insulating film 1312 have different volumes from each other.

According to the above-described configuration, the amount of hydrogen to be filtrated into the cavity can be changed, so that cavity pressures that are different from one another for each sensor on the same substrate can be achieved at a low cost.

What is claimed is:

1. A MEMS device having a cavity, comprising:
an insulating film containing hydrogen in vicinity of the cavity; and
a hydrogen barrier film covering the insulating film.

2. The MEMS device according to claim 1,
wherein the insulating film is disposed above the cavity through a first silicon substrate.

3. The MEMS device according to claim 1,
wherein, on a plane perpendicular to a film thickness direction of the insulating film, the insulating film is disposed on an inner side of outer periphery of the MEMS device.

4. The MEMS device according to claim 1,
wherein the insulating film is a silicon oxide film containing TEOS or silane as a raw material.

5. The MEMS device according to claim 1,
wherein the hydrogen barrier film is a silicon nitride film.

6. The MEMS device according to claim 1 further comprising:
a silicon substrate below the cavity; and
a second hydrogen barrier film that covers a lower surface of the silicon substrate.

7. The MEMS device according to claim 1,
wherein hydrogen molecules are contained in the cavity, and
a volume ratio of the hydrogen molecules inside the cavity exceeds 50 percent.

8. The MEMS device according to claim 1 comprising:
a first silicon substrate above the cavity,
wherein the hydrogen barrier film also covers the first silicon substrate.

9. The MEMS device according to claim 1,
wherein, on a plane perpendicular to a film thickness direction of the insulating film, the insulating film is disposed on an inner side of outer periphery of the cavity.

10. The MEMS device according to claim 1 further comprising:
a movable electrode connected to a movable part inside the cavity;
a fixed electrode inside the cavity;
a first silicon substrate above the cavity; and
a second silicon substrate below the cavity,
wherein an acceleration applied to the MEMS device is measured by detecting a change amount in a capacitance between the movable electrode and the fixed electrode.

11. The MEMS device according to claim 1,
wherein the MEMS device is an acceleration sensor or an angular velocity sensor.

12. The MEMS device according to claim 8,
wherein a separation layer made of a material whose crystallinity is lower than that of single crystal silicon is formed between the insulating film and the cavity, and
the separation layer is formed so as to penetrate the first silicon substrate.

13. The MEMS device according to claim 12,
wherein the separation layer is formed of a material of only an insulating film made of silicon oxide, or the insulating film made of silicon oxide and an embedding material made of polysilicon.

14. A composite-type MEMS device having a plurality of cavities, comprising:
a first insulating film containing hydrogen above a first cavity;
a second insulating film containing hydrogen above a second cavity; and
a hydrogen barrier film covering the first insulating film and the second insulating film,
wherein the first insulating film and the second insulating film have different volumes from each other.

15. The MEMS device according to claim 14,
wherein an inner pressure of the first cavity is larger than an inner pressure of the second cavity, and
the volume of the first insulating film is larger than the volume of the second insulating film when being converted into a cavity volume ratio.
